(19) United States
(12) Patent Application Publication
(10) Pub. No.: US 2024/0136195 A1
(43) Pub. Date: Apr. 25, 2024

(54) Polymer Removal via Multiple Flash Steps during Plasma Etch

(71) Applicant: Tokyo Electron Limited, Tokyo (JP)

(72) Inventors: Alec Dorfner, Miyagi (JP); Minjoon Park, Albany, NY (US); Minseok Oh, Albany, NY (US)

(21) Appl. No.: 17/970,899

(22) Filed: Oct. 20, 2022

(51) Int. Cl. H01L 21/3065

(52) U.S. Cl. CPC H01L 21/30655

(57) ABSTRACT

A method of etching a target material using plasma includes cyclically performing the steps of an etch step for a first duration to etch a target material exposed in openings of a patterned mask material, and a flash step for a second duration after the first duration to remove polymer material accumulated at the openings during the etch step. The etch step is performed by generating plasma from an etch precursor gas including an etchant species. The target material may be a dielectric, such as a dielectric target material that includes an oxide. The flash step is performed by generating plasma from a flash precursor gas. Bias power may be provided to the substrate during the flash step. The flash species is different from the etchant species. The flash precursor gas may include oxygen and no fluorocarbons.

### TECHNICAL FIELD

The present invention relates generally to methods of plasma etching, and, in particular embodiments, to methods, apparatuses, and systems that use multiple flash steps to remove polymer during a plasma etching process.

### BACKGROUND

Microelectronic device fabrication typically involves a series of manufacturing techniques that include formation, patterning, and removal of a number of layers of material on a substrate. Etch masks may be formed (e.g. deposited, grown) to protect regions of the substrate and allow for pattern transfer via etching. Wet or dry etching processes may be used, with plasma etching processes being an example of a dry etching process.

Etching processes are used in a variety of semiconductor processing areas such as in memory manufacture. One category of etching processes is high aspect ratio (HAR) etching including processes such as high aspect ratio contact (HARC) etches for contact formation. Obtaining a high aspect ratio during etching is important for a variety of semiconductor processes such as during NAND formation (e.g. 3D-NAND), NOR gate formation, and others.

Defects may occur when transferring a pattern to an underlying layer. For example, the features transferred to the underlying layer may have any number of undesirable defects such as broadening or narrowing, inconsistency in size or location, distortion (e.g. deviation from initial circular shape), and non-vertical sidewalls. Additionally, the edges of the transferred pattern may not be as smooth as the mask pattern, a metric referred to as edge roughness.

Over the course of an etching process polymer can accumulate on the sidewall of the mask. For example, polymer may build up in openings of the mask. This polymer shrinks the aperture, reducing the area through which ions and radicals can pass. The critical dimensions (CDs) of the mask may be undesirably altered by the polymer leading to feature defects. Further, reduced flux of particles to the etch front undesirably slows the etch rate and may exacerbate detrimental effects such as aspect ratio dependent etch-rate (ARDE). Therefore, etching processes which control polymer buildup during the etching process may be desirable.

### SUMMARY

In accordance with an embodiment of the invention, a method of etching a target material using plasma includes cyclically performing the steps of an etch step for a first duration to etch a target material exposed in openings of a patterned mask material, and a flash step for a second duration after the first duration to remove polymer material accumulated at the openings during the etch step. The etch step is performed by generating plasma from an etch precursor gas including an etchant species. The flash step is performed by generating plasma from a flash precursor gas. The flash species is different from the etchant species. The flash precursor gas includes oxygen and no fluorocarbons.

In accordance with another embodiment of the invention, a method of etching a dielectric using plasma includes cyclically performing the steps of performing an etch step for a first duration to etch a dielectric exposed in openings of a patterned hard mask material of a substrate, and performing a flash step for a second duration after the first duration to remove polymer material accumulated at the openings during the etch step. The etch step is performed by generating plasma from an etch precursor gas including an etchant species. The flash step is performed by generating plasma from a flash precursor gas and providing bias power at the substrate. The dielectric includes an oxide. The etchant species has greater reactivity toward the oxide than toward the hard mask material. The flash precursor gas includes a flash species that has greater reactivity toward the polymer material than toward the oxide.

In accordance with still another embodiment of the invention, a plasma etching system includes a plasma chamber, a substrate holder disposed in the plasma chamber and configured to support a substrate, and a controller operationally coupled to the chamber. The controller is configured to cyclically perform an etch step for a first duration to etch a target material exposed in openings of a patterned mask material of the substrate and a flash step for a second duration after the first duration to remove polymer material accumulated at the openings during the etch step. The etch step is performed by generating plasma from an etch precursor gas including an etchant species. The flash step is performed by generating plasma from a flash precursor gas including a flash species. The flash species is different from the etchant species. The flash precursor gas includes oxygen and no fluorocarbons.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 schematically illustrates an example substrate including a mask material overlying a target material and qualitatively shows polymer buildup over time during a plasma etching process in accordance with embodiments of the invention;

FIG. 2 schematically illustrates an example substrate including polymer material with both primary and secondary facets and another example substrate including polymer material with only a primary facet in accordance with embodiments of the invention;

FIG. 3 schematically illustrates a timing diagram and a corresponding substrate of an example method of etching a target material including multiple etch steps and flash steps performed cyclically to remove polymer material accumulated at openings during the etch steps in accordance with embodiments of the invention;

FIG. 4 schematically illustrates an example plasma etching system including a controller operatively coupled to a plasma chamber and configured to deliver an etch precursor gas during etch steps and a flash precursor gas during flash steps in accordance with embodiments of the invention;

FIG. 5 schematically illustrates two timing diagrams of example methods of etching a target material where the total etch time is the same between the two timing diagrams in accordance with embodiments of the invention;

FIG. 6 schematically illustrates two timing diagrams of example methods of etching a target material where both the total etch time and the total flash time are the same between the two timing diagrams, but the number of flash steps is varied in accordance with embodiments of the invention;

FIG. 7 illustrates an example method of etching a target substrate in accordance with embodiments of the invention;

FIG. 8 illustrates another method of etching a target substrate in accordance with embodiments of the invention; and

FIG. 9 qualitatively illustrates example dimples exhibiting greater defects contrasted with example dimples exhibiting lesser defects in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope. Unless specified otherwise, the expressions “around”, “approximately”, and “substantially” signify within 10%, and preferably within 5% of the given value or, such as in the case of substantially zero, less than 10% and preferably less than 5% of a comparable quantity.

Polymer formation often occurs during plasma etching processes. For example, in plasma etching processes that use fluorocarbons as etchants (e.g. compounds having the formula CₓF_{y}, also abbreviated as CFs herein), dissociation within the plasma leads to CF polymer formation. This polymer formation reduces the size of openings in the mask layer resulting in fewer plasma species (e.g. ions and radicals) from reaching the bottom of the mask features.

One major disadvantage is to decrease the etch rate during the etching process over time because fewer ions and radicals reach the bottom of mask features (e.g. holes and trenches). The polymer deflects the plasma species that make it into the mask features from their original trajectory decreasing their verticality. Further, the reduction in etchant species at the bottom of features becomes more dramatic as the aspect ratio increases. Therefore, polymer accumulation at the mask's sidewall (e.g. necking) may also be an important source of the common undesirable effect of aspect ratio dependent etch-rate (ARDE).

Polymer deflection can also undesirably increase the lateral etch rate relative to the vertical etch rate and cause undesirable effects such as bowing of the sidewalls. The shape of the polymer at the top of the mask (which may be referred to as the secondary facet or 2° facet) typically has an irregular (e.g. rounded, lateral, but non-circular) shape. This irregularity may get projected into underlying layers resulting in undesirable distortion and feature edge roughness (e.g. contact edge roughness CER) into the dimple into the underlayer.

Conventional methods for preventing undesirable effects from polymer buildup involve tuning parameters such as high frequency (HF) power, pressure, and relative gas flowrates. For example, gas flowrates may be adjusted as decreasing CF flowrates (e.g. C₄F₆) and/or increasing other flowrates such as oxygen (O₂) flowrates. This may be to make the plasma more lean and alter the gas chemistry of the plasma to include fewer large CF plasma species. For example, smaller CF plasma species may make it further into the mask openings than larger CF species which may tend to stick near the top of the mask.

Yet, this conventional method of gas tuning has many drawbacks. Conventional gas tuning has an inherent tradeoff between increasing overall etch rate and decreasing mask erosion. That is, the gas tuning methods that increase the etch rate also decrease polymer build up. For example, mask selectivity may be undesirably reduced when the etch rate is increased resulting in negative effects that are propagated to underlying layers such as a large bowing critical dimension (CD).

Therefore, decoupling polymer accumulation in the top region of the mask from polymer accumulation at the sidewall during etching is desirable. For instance, polymer accumulation in the top region of the mask may cause narrowing of mask openings (small neck CD) through the formation of the 2° facet. However, polymer flux to the sidewall (e.g. oxide sidewall) may be desirable for passivation during the etching. The inventors have determined that the polymer accumulation in the top region of the mask can be decoupled from the sidewall polymer accumulation by incorporating one or more flash steps into the etch step.

The embodiment methods described herein introduce one or more separate flash steps for managing polymer accumulation during a plasma etching process. The separate flash steps enable etch steps to have higher polymer flux with the advantage of avoiding clogging, tapering, distortion, and/or CER. In particular, the flash steps include plasma generated from a flash precursor gas that includes a flash species used to remove polymer material without damaging mask material. The flash species is different than an etch species included in an etch precursor gas used to generate a plasma for etch steps. For example, the flash species may include oxygen (i.e. oxygen-containing compounds). Additionally, the flash precursor gas may further include an inert species, such as a noble gas like argon (Ar), krypton (Kr), and others. Bias power may be applied during the flash step to increase ion verticality for improved removal of the secondary facet. The target material may be a dielectric such as an oxide, a nitride, or a stack thereof (e.g. ONO). The mask material may be a hard mask material and may include carbon. For instance, the mask material may be an amorphous carbon layer (ACL).

Through the implementation of a cyclic flash process, polymer accumulation can be advantageously be controlled without directly impacting sidewall passivation during the etch step. In many etching applications (e.g. HAR etches such as a HARC etch), polymer accumulation may be the driving force behind such undesirable effects such as distortion and CER. That is, distortion and CER are persistent issues in dielectric HARC etch processes. Consequently, control of polymer buildup during the etching process has the advantages of controlling distortion and CER.

An additional advantage is the ability to consistently and selectively remove the 2° facet of the polymer buildup (i.e. the secondary rounded irregular facet). This is beneficial for decoupling the desirable sidewall passivation afforded by polymer accumulation on the sidewall from the undesirable polymer buildup at the top of the mask features. Removing the 2° facet also advantageously reduces the amount of plasma species (e.g. ions) that are deflected into the sidewall. With fewer species impacting the sidewalls, lateral etching effects such as undesirable bowing can also be reduced.

Variation in flash parameters can provide optimization benefits for a given etching process. Flash chemistry can be tailored independently from the etch chemistry as needed (e.g. to react more aggressively with the polymer or to increase ion sputtering). The duration of each flash step and/or the total flash duration for the entire etching process may also be tailored to optimize etch rate, total etch time, bottom to top ratio (B/T ratio), dimple CD, distortion, and contact edge roughness (CER) improvements, among others.

The inventors have also determined that the effectiveness of a flash step at removing polymer is subject to diminishing returns as the flash duration is increased. That is, an early portion of each flash step has the largest impact on mitigating negative effects such as B/T ratio, distortion, and CER. As the flash duration is increased, the added benefit is smaller and smaller until no benefit is obtained by extending the flash duration (e.g. because all of the polymer is removed and/or there are chamber effects, substrate cooling, etc.).

As a result, when multiple flash steps are utilized, additional control over the efficiency of the etching process can be achieved. For instance, the including more flash steps of shorter duration can advantageously maximize the highly effective early portion of each flash step and avoid flash step inefficiency. Further, controlling the frequency of flash steps for a given etching process carries the benefit of tuning the flash steps to be applied when there is an optimal amount of polymer accumulation to achieve the maximum benefits.

Conventional methods have used cleaning steps in contexts other than those described here. For example, polymer buildup is a problem in a variety of processes, including other etching processes. Accordingly, conventional etching methods have used cleaning steps to remove polymer buildup with varying success. For example, in the specific example of a silicon oxynitride (SiON) mask, CF₄-based cleaning steps have been used to remove silicon oxide or silicon oxynitride buildup during ACL etches and silicon etches (to form shallow trench isolation).

However, the inclusion fluorocarbons such as CF₄ in the flash steps described herein would often be counter productive, working towards the opposite result (polymer accumulation rather than polymer removal). Further, many conventional cleaning steps do not use bias power during the cleaning step (e.g. to avoid substrate damage) and are consequently less effective in general and also at targeting formations such as the secondary facet. Conventional cleaning steps may also use etch chemistry that cannot be allowed to mix with the cleaning step chemistry requiring the plasma chamber to be evacuated between every step.

The methods described herein improve upon these conventional methods by incorporating one or more features such as oxygen-based, fluorocarbon-free flash chemistry, bias power during the flash step, heavy inert gas bombardment, purge-free gas switching, dielectric etch target (e.g. oxide, ONO, etc.), and enhanced control over polymer accumulation by tailoring flash frequency, flash-to-etch ratio, total flash time, and total etch time, among others.

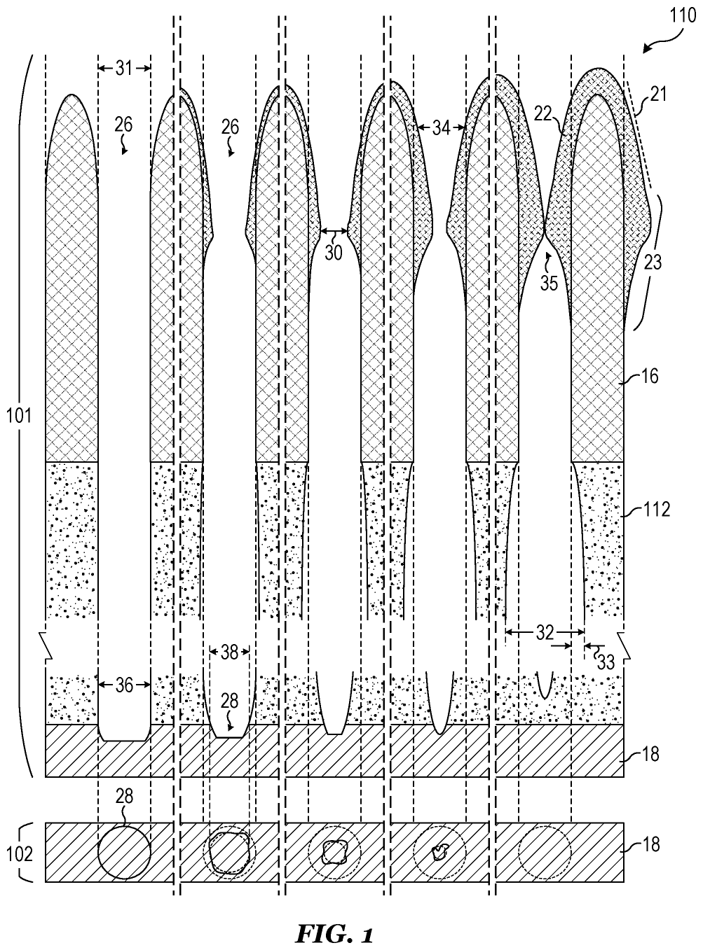

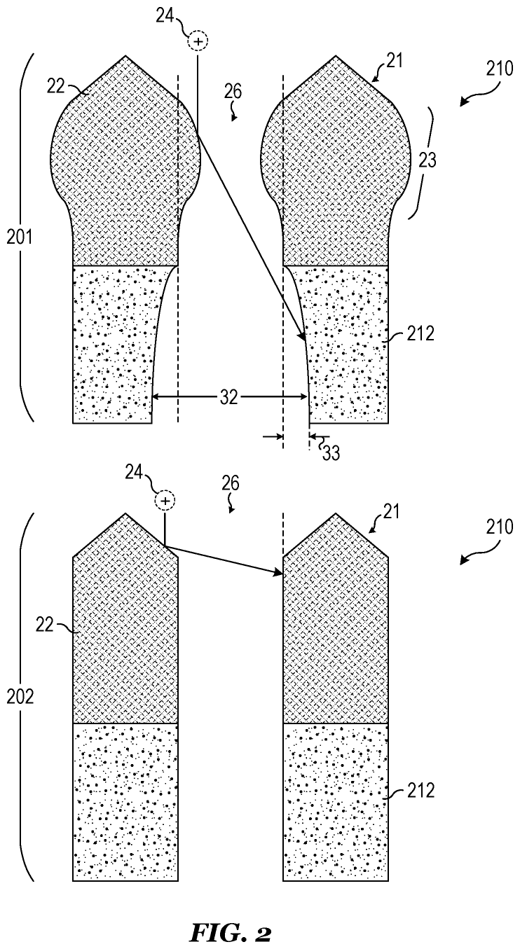

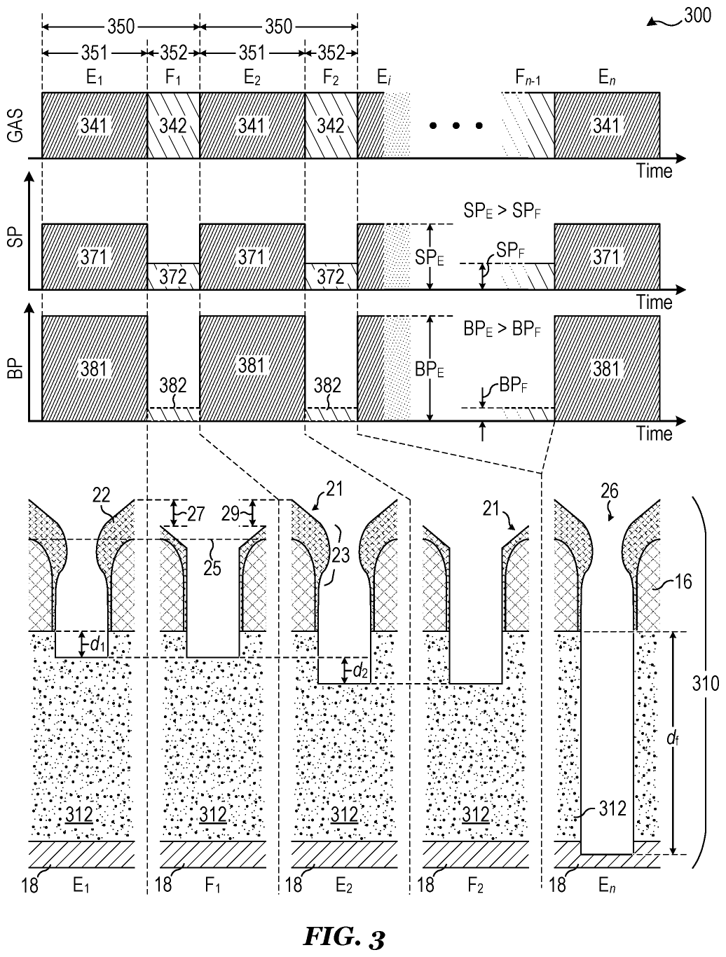

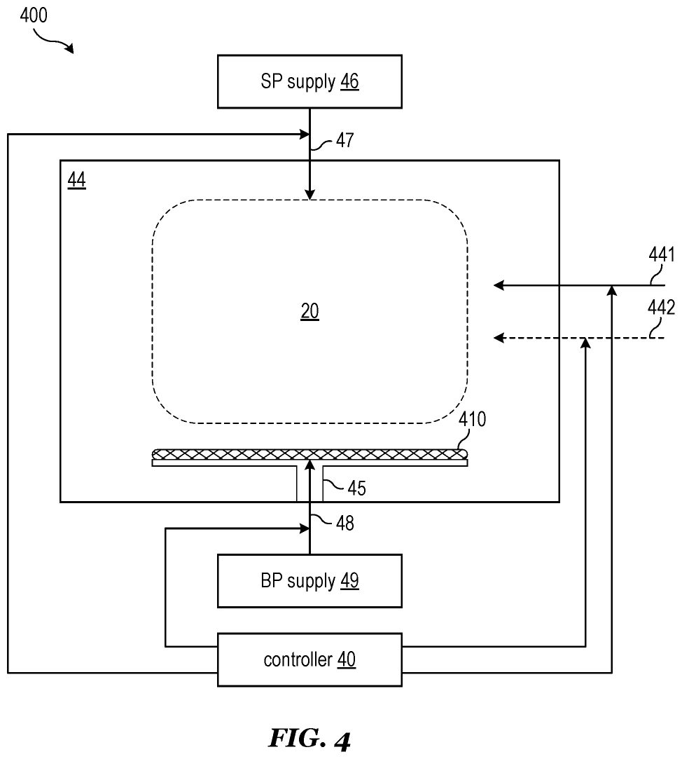

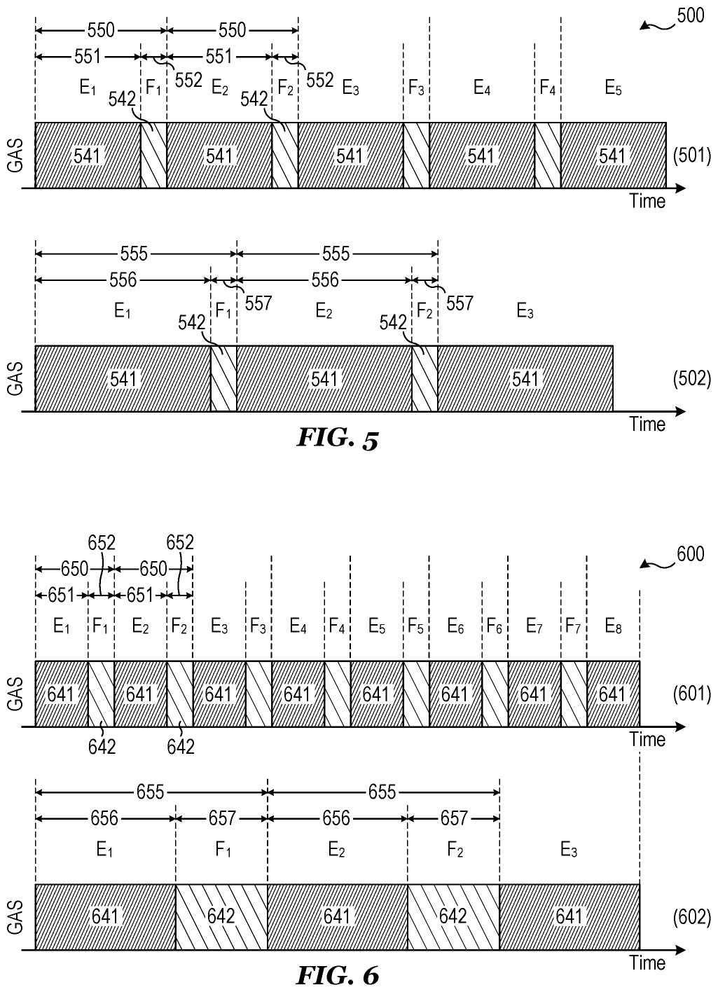

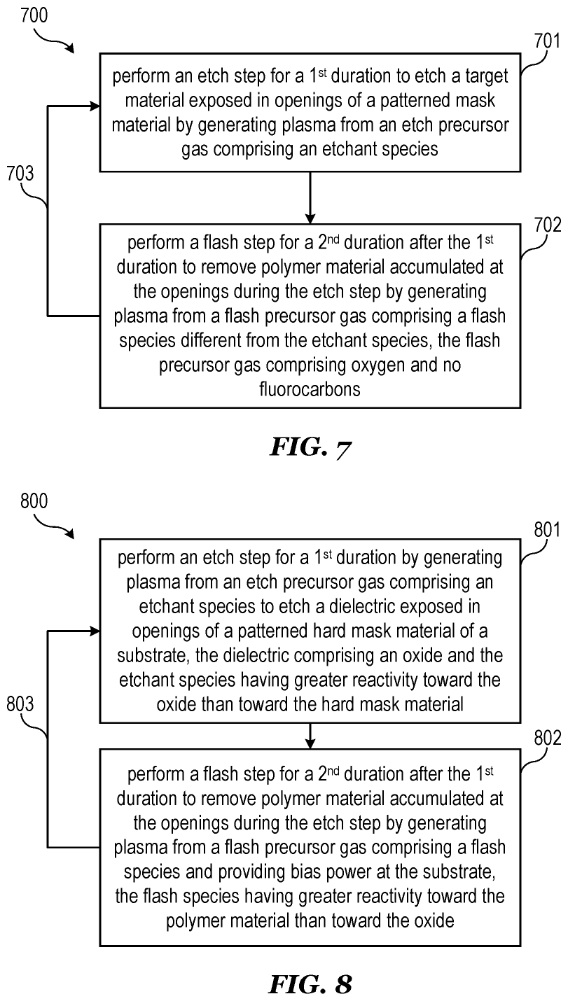

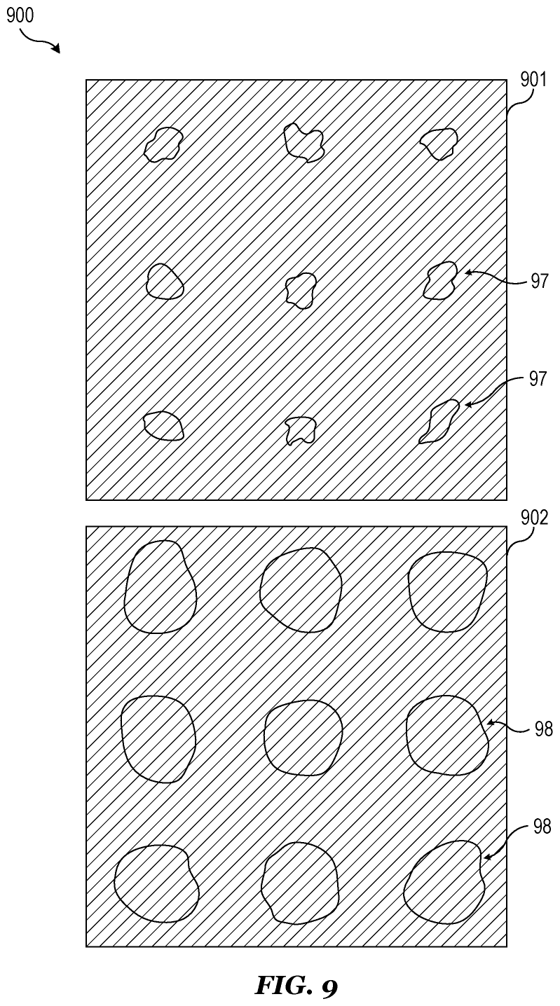

Embodiments provided below describe various methods, apparatuses and systems of plasma etching, and in particular, to methods, apparatuses, and systems that use multiple flash steps to remove polymer during a plasma etching process. The following description describes the embodiments. FIG. 1 is used to describe an example substrate. FIG. 2 is used to describe two example substrates that are contrasted by the effects of a secondary facet of a polymer material. An example method of etching a target material is described using FIG. 3. An example plasma etching system configured to perform methods of etching a target material is described using FIG. 4. Two more example methods of etching a target material that demonstrate the effects of holding total etch time and total flash time constant are described using FIGS. 5 and 6 while FIGS. 7 and 8 are used to describe another two methods of etching a target material. FIG. 9 is used to qualitatively illustrate differences between greater defects and lesser defects in dimples.

FIG. 1 schematically illustrates an example substrate including a mask material overlying a target material and qualitatively shows polymer buildup over time during a plasma etching process in accordance with embodiments of the invention.

Referring to FIG. 1, a side view 101 and a top view 102 show a substrate 110 includes a mask material 16 overlying a target material 112. The mask material 16 is patterned to form openings 26 that are used to transfer a desired pattern from the mask layer including the mask material 16 into the target material 112 and optionally an underlying layer 18 beneath the target material 112. The substrate 110 may be any suitable substrate, such as an insulating, conducting, or semiconducting substrate with one or more layers disposed thereon. One example category of possible substrates would be one of the many types of semiconductor wafer (silicon, silicon-on-insulator, germanium, gallium arsenide, etc.).

This configuration may represent a general etching process and is not limited to any specific materials or patterns. For example, the target material 112 may be any suitable material, but is a dielectric in various embodiments. In one embodiment, the target material 112 is a dielectric that includes an oxide. For example, the dielectric may include silicon dioxide (SiO₂). Other oxides are of course also possible such as aluminum oxide (Al₂O₃, commonly referred to as sapphire), and others. In one embodiment, the dielectric includes a nitride, such as silicon nitride (Si₃N₄).

The target material 112 may be a homogeneous material (such as SiO₂) of it may be stack of any number of materials. In some embodiments, the target material 112 is a stack including an oxide and a nitride, and is an alternating stack of oxides and nitrides (often referred to as an ONO stack) in one embodiment. For example, the target material 112 may be an ONO stack including tens to hundreds of alternating SiO₂ and Si₃N₄ layers. Such a configuration may be used in various applications such as a HARC etch for memory (e.g. 3D-NAND, DRAM, etc.). In the specific example of a HARC etch, the underlying layer 18 may be a semiconductor layer (e.g. a device layer) with which electrical contact is being made using the plasma etching process.

The mask material 16 may also be any suitable material (i.e. a material with properties that the enable patterned mask material to protect underlying portions of the target material 112 while exposed portions of the target material 112 (i.e. in the openings 26) are etched away during a plasma etching process. In various embodiments, the mask material 16 is a hard mask material, such as for HAR etches. In some embodiments, the mask material 16 includes carbon and is an ACL in one embodiment. Other possible materials for the mask material 16 include polysilicon, a tungsten-containing material, among others. In the specific example where the target material 112 is a dielectric, the mask material 16 may be chosen to be resistant to fluorocarbon (CF) chemistry as fluorocarbons (especially higher molecular weight fluorocarbons having at least two carbon atoms) may be used to etch the target material 112.

As time passes during an etch step of the etching process, a polymer material 22 builds up on the mask material 16, especially at the tops of features, such as on and around the openings 26. FIG. 1 shows several examples of the polymer material 22 accumulating around the openings 26 to varying degrees. Each of the examples may represent a different etch step in a cyclic process. Possible qualitative effects of different average levels of polymer buildup during the etching process as whole are shown at the bottom of FIG. 1.

There are many different types of polymer material that may build up depending on the properties of the target material 112 and the types of etch precursor gases used to generate the plasma. In various embodiments, the polymer material 22 is an organic polymer (i.e. including carbon). For example, the carbon may be introduced from fluorocarbon etchants (e.g. CF₄, C₂F₆, etc.) or may come from the mask material 16, such as for ACL masks. In some cases, the presence of fluorocarbons during the etch step interact with various materials of the substrate 110 to form the polymer material 22.

As shown, the polymer material 22 may accumulate at the openings 26 of the mask material 16 in a particular way that gives rise to a substantially flat primary facet 21 and a rounded secondary facet 23 that bulges out into the openings 26. Initially, the openings 26 are clear and have a mask width 31 allowing for the maximum flux of plasma species to enter the openings 26 and reach the bottom of the features being etched. However, over time the polymer material 22 builds up and reduces the minimum size of the openings 26, which is referred to as the NCD 30 (neck CD). The NCD 30 becomes smaller and smaller relative to the mask width 31 and a variety of undesirable effects may occur.

For example, in an extreme case the NCD 30 becomes zero and the openings 26 close (as shown by arrow 35). This can cause the etching of the target material 112 to stop and the desired etch depth (e.g. the underlying layer 18) may be unreachable. While this worst-case-scenario may not always happen (depending on several factors related to the etch step parameters), the polymer material 22 cannot be prevented from accumulating using etch step parameters for many plasma etching processes such as those using fluorocarbons. Moreover, even small amounts of polymer accumulation may have undesirable effects on the results of the etching process.

For instance, various CDs such as TCD 34 (top CD, measured near the top of the openings 26, such as between 80% and 100% of the feature height), BCD 36 (bottom CD, similarly measured near the bottom of the openings 26, such as between 0% and 20% of the feature height), and DCD 38 (dimple CD, such as measuring the mean diameter or the maximum size of a dimple 28 formed in the underlying layer 18), among others. One specific CD that may be affected and lead to the degradation of other CDs is bowing CD 32, resulting from plasma species being deflected by, for example, the secondary facet 23. The bowing CD 32 is the maximum width of the feature and may also be measure per side (shown as per side bow 33).

In practice, the dimple 28 will deviate from the ideal shape and size of the features that the patterned mask material 16 is designed to transfer. Minimizing these deviations is desirable and may be achieved by reducing the amount of time that polymer buildup is present in the openings 26. Some common measures of deviation for the dimples 28 are distortion (which can be expressed various ways that measure the uniformity of the dimple 28 such as ellipticity expressed as minimum diameter divided by maximum diameter or minimum radius divided by maximum radius), and CER which measures the how smooth the boundary of the dimple 28 is (e.g. expressed as a three-sigma deviation of the radius or the diameter). As shown, the dimple 28 becomes more and more distorted and rough as the polymer material 22 builds up in the openings 26.

FIG. 2 schematically illustrates an example substrate including polymer material with both primary and secondary facets and another example substrate including polymer material with only a primary facet in accordance with embodiments of the invention. The substrates of FIG. 2 may be a specific implementation of other substrates described herein such as the substrate of FIG. 1, for example. Similarly labeled elements may be as previously described.

Referring to FIG. 2, a substrate 210 includes a polymer material 22 overlying a target material 212 as before. Although an example shape of the polymer material 22 with the primary facet 21 and the secondary facet 23 is shown, the shape of the polymer may vary while still having the primary facet 21 and the secondary facet 23. Accordingly, a conceptually simplified version of the polymer material 22 is provided to highlight fundamental effects of the accumulation of the polymer material 22 at the openings 26.

It should be noted that here and in the following a convention has been adopted for brevity and clarity wherein elements adhering to the pattern [x10] where ‘x’ is the figure number may be related implementations of a substrate in various embodiments. For example, the substrate 210 may be similar to the substrate 110 except as otherwise stated. An analogous convention has also been adopted for other elements as made clear by the use of similar terms in conjunction with the aforementioned numbering system.

In the first example 201, the polymer material 22 has accumulated and formed a shape that includes both a primary facet 21 and a polymer material 22. Notably, the secondary facet 23 extends into the openings 26 and have a rounded surface (as opposed to the substantially linear surface of the primary facet 21). It may also be worth mentioning that the primary facet 21 can be entirely polymer, include mask material, or be entirely mask material (e.g. if the polymer that accumulates at the top of the mask is continuously etched away).

During the etch step, ions 24 are accelerated toward the substrate 210 (i.e. given vertical velocity relative to the substrate 210) with the intent of introducing a vertical flux of the ions 24 to the bottom of the feature and increase the etch depth. However, as the secondary facet 23 grows the ions 24 may be deflected with greater and greater probability resulting in fewer ions 24 reaching the bottom of the feature and more ions 24 impacting the sidewalls of the feature. This is one source of undesirable bowing effects (bowing CD 32 and per side bow 33 as shown).

In the second example 202, some of the polymer material 22 still remains, but only the primary facet 21 is present (i.e. the secondary facet 23 has been removed). In this scenario, fewer of the ions 24 are deflected into the sidewalls and there is a larger vertical flux of ions 24 to the bottom of the feature. Consequently, this may be a desirable goal for polymer removal that has additional advantages over simply removing all of the polymer. For example, polymer that that does not negatively affect the etching process remains at the top of the openings 26 and protects the mask material (not shown) from eroding during the etch step. Some amount of polymer is often desirable to improve selectivity.

FIG. 3 schematically illustrates a timing diagram and a corresponding substrate of an example method of etching a target material including multiple etch steps and flash steps performed cyclically to remove polymer material accumulated at openings during the etch steps in accordance with embodiments of the invention. The method of FIG. 3 may be performed using any of the substrate as described herein, such as the substrates of FIGS. 1 and 2, for example. Similarly labeled elements are as previously described.

Referring to FIG. 3, a method 300 of etching a target material 312 (such as a dielectric) using plasma includes repeatedly performing a cycle 350 that alternates an etch step Eᵢ and a flash step Fᵢ over until reaching n etch steps (e.g. cyclically performing a series of steps that make up the cycle 350 until n etch steps have been performing). Although the last cycle (e.g. the n^{th} cycle) is shown as not including a flash step Fₙ, a final flash step may be included if desired. The number of cycles n may be any suitable value, and may depend on a variety of factors such as the desired etch depth d_{f}, the rates of accumulation and removal of the polymer material 22, the etch rate, the chemistry (both etch chemistry and flash chemistry), and others.

The etch step Eᵢ is performed for an etch step duration 351 during which an etch precursor gas 341 is provided near a substrate 310 that includes the target material 312. A plasma is generated from the etch precursor gas 341 (e.g. by applying etch source power 371 (SP) at an etch source power level SP_{E}). The etch precursor gas 341 includes an etchant species with chosen selectivity to etch a target material 312 exposed in the openings 26 of a patterned mask material 16. For example, the etchant species may have greater reactivity toward the target material 312 (e.g. a dielectric such as an oxide) than toward the mask material 16 (e.g. a hard mask material such as an ACL).

The effects of a first etch step Eᵢ are shown in FIG. 3. During the etch step Eᵢ, bias power (BP) may be applied as etch bias power 381 at an etch bias power level BP_{E} to impart vertical velocity to charged species of the plasma (such as positive ions of the etchant species). The plasma species including the ions etch the target material 312 to a first etch depth d₁ during the etch step duration 351. As previously discussed, a polymer material 22 is accumulated on the mask material 16 forming a shape that reduces the size of the openings 26 and includes a primary facet 21 and a secondary facet 23.

The flash step Fᵢ is performed for a flash step duration 352 during which a flash precursor gas 342 is provided near the substrate 310 to remove polymer material 22 accumulated at the openings 26 during the etch step Eᵢ. A plasma is generated from the flash precursor gas 342 (e.g. by coupling flash source power 372 to the flash precursor gas 342 at a flash source power level SP_{F}). As shown, in various embodiments, SP_{F} is less than SP_{E}. This may be, for example, to prevent damage to materials other than the polymer material 22 such as the mask material 16 (or even to prevent to much damage to the polymer material 22 because, as mentioned above, some polymer is often beneficial to the etching process).

The flash precursor gas 342 includes a flash species that is chosen to interact with the polymer material 22 such that the flash species works to remove the polymer material 22 during the flash step Fᵢ. For instance, the flash species may react with the polymer material 22. Additionally, the flash species may have some selectivity to the polymer material 22 such as having greater reactivity toward the polymer material 22 than toward the target material 312. In various embodiments, the flash precursor gas 342 includes oxygen (e.g. O₂). Additionally, in the flash precursor gas 342 includes no fluorocarbons (i.e. does not include any fluorocarbons), especially in circumstances where fluorocarbons are a significant source of polymer accumulation.

The effects of the first flash step F₁ are also shown. During the flash step F₁, bias power may also be applied as flash bias power 382 at a flash bias power level BP_{F}. Some amount of bias power may advantageously impart vertical velocity to ions of the plasma and improve the selectivity of the flash step to the secondary facet 23 (e.g. the rounded protrusions of the secondary facet 23 are less stable than the supported primary facet 21 and therefore may be more susceptible to bombardment effects knocking polymer of the secondary facet 23 free). However, as with the source power (and to a greater degree in many embodiments) BP_{F} is less than BP_{E}.

The overall effect of the flash step F₁ is to remove polymer material 22. Specifically, the secondary facet 23 of the polymer material 22 may be removed or reduced such that the openings 26 are widened to be closer to the original mask width (e.g. the NCD of the openings 26 is increased during the flash step). The primary facet 21 may also be affected. Advantageously, there is no requirement to fully remove the primary facet 21 (and indeed it may be beneficial to leave it along with, for example, some polymer passivation on sidewalls as shown). In this qualitative example, the polymer height reduction 27 does not result in the original mask material 16 being exposed (i.e. the mask height may be unaffected by the flash step). Additionally, even if the primary facet 21 is fully removed, its prior presence combined with the preferential removal of the secondary facet 23 may advantageously reduce mask height reduction during the flash step.

As shown, the second etch step E₂ results in the target material 312 being etched to a second etch depth d₂ and accumulation of the polymer material 22 to form the familiar structure with a primary facet 21 and a secondary facet 23. The polymer buildup may also result in a polymer height increase 29 (conceptually shown as equal to the polymer height reduction 27, but of course may be less or more). The second flash step F₂ then again removes the secondary facet 23 and some of the primary facet 21 and the cycle 350 is repeated as desired.

In this ideal situation there will never be a mask removal cost for repeatedly performing the flash step. However, in practice, the rate of polymer accumulation may be less that the rate of polymer removal and mask removal may eventually occur. For example, the inventors have determined that at least for some conditions up to 10 flash steps may be performed with no selectivity cost, but these results will heavily depend on the specific details of a given application.

The etching process may be terminated after a desired final etch depth d_{f} is reached. For applications where the goal is to breach an underlying layer 18 with the etch, the method 300 of etching the target material may end once the desired pattern is transferred into the underlying layer 18 after n etch steps (such as a semiconductor device layer during a HARC etch, for example). Several potential advantages achieved as a final result of implementing the method 300 is improved distortion, CER, DCD (dimple CD), and bowing CD. Additionally, the method 300 can also reduce ARDE due to the increased average NCD (neck CD) allowing etchant species to more consistently reach the bottom of the features during the etching process.

As shown in this specific example, the method 300 may be performed with no purge step between the etch steps and flash steps (e.g. without evacuating the plasma chamber between steps). This may advantageously reduce the overall process time and improve simplicity. The lack of purge steps may be made possible, for example, because of the chosen etch chemistry, flash chemistry, and etch parameters such as power settings, step durations, and the materials of the substrate 310.

It should also be mentioned that while optimized recipes will derive some benefit, un-optimized recipes could derive even more benefit because the ability to effectively remove polymer may allow for more polymer to be generated during etch steps with fewer consequences. As a result, recipes may advantageously be optimized in a different way; optimization may take into account that more polymer can be generated and other aspects may be optimized such as etch rate or selectivity.

Various flash step options may increase the time efficiency of the flash step, or the etching process as a whole. For example, the inventors have determined that the greatest benefit to removing the secondary facet is during the beginning portion of the flash step. This may be, for example, because the top portion of the secondary facet is rapidly removed which quickly allows more ions to enter the opening without being deflected. Additionally, the inventors have observed that under certain conditions there may be diminishing returns for flash steps that are too long. For example, benefits to CDs, distortion, CER, and ARDE may be lessened (or even harmed) while detrimental effects such as mask erosion may occur. Longer flash steps of course also result in longer overall process times.

In various embodiments, the flash step duration 352 is less than about 40 s and is less than about 20 s in some embodiments. In some applications, 20 s may strike a desirable balance and so in one embodiment, the flash step duration 352 is about 20 s. However, more rapid flash steps also appear to be beneficial (as opposed to fewer, longer flash steps). Therefore, in other embodiments, the flash step duration 352 is less than about 10 s and is about 10 s in one embodiment.

The number of flashes performed during the etching process may influence the degree of benefit for nearly all parameters. For example, distortion, DCD, BT ratio (bottom-to-top ratio: BCD/TCD), and CER may all improve with a greater raw number of flash steps. Some metrics such as bowing may derive general benefit from the flash step, but may not further improve by simply adding more flash steps.

FIG. 4 schematically illustrates an example plasma etching system including a controller operatively coupled to a plasma chamber and configured to deliver an etch precursor gas during etch steps and a flash precursor gas during flash steps in accordance with embodiments of the invention. The plasma etching system of FIG. 4 may be used to perform any of the methods described herein, such as the method of FIG. 3, for example. Similarly labeled elements may be as previously described.

Referring to FIG. 4, a plasma etching system 400 includes a controller 40 operatively coupled to a plasma chamber 44 and configured to provide an etch precursor gas 441 and a flash precursor gas 442 in the plasma chamber 44. The controller 40 may be further configured to cyclically perform the etch step by providing the etch precursor gas 441 and the flash step by providing the flash precursor gas 442 without evacuating the plasma chamber 44 between steps.

The controller 40 is further coupled to a source power supply 46 that is configured to couple source power to gas within the plasma chamber 44. For example, the source power supply 46 may be any suitable type of source power supply such as an RF power supply. The source power supply 46 is configured to generate plasma 20 in the plasma chamber 44. The plasma 20 may be an inductively coupled plasma (ICP), capacitively coupled plasma (CCP), or any other desired type.

A substrate 410 including patterned mask material with openings that expose a target material may be provided into the plasma chamber 44. A substrate holder 45 may be included in the plasma chamber 44 to support the substrate 410. The substrate holder 45 may be any suitable type of holder including mechanical, vacuum, or electrostatic chucks. The controller 40 may be operationally coupled to a bias power supply 49 that is in turn coupled to the substrate 410 (e.g. via the substrate holder 45) and configured to deliver bias power 48 at the substrate 410.

The source power supply 46 may be configured to deliver higher wattage power during the etch step and lower wattage power during the flash step. In various embodiments, the SP_{E} is between about 3 kW and about 8 kW and is between about 4 kW and about 5 kW in some embodiments. In contrast, during the flash step, the source power supply 46 is configured to deliver lower power. In various embodiments, the SP_{F} is between about 500 W and about 2 kW, and is about 1 kW in one embodiment.

Similarly, the bias power supply 49 may also be configured to deliver higher wattage power (e.g. even higher than the source power) during the etch step and lower wattage power during the flash step. In some embodiments, BP_{E} is greater than about 2 kW while BP_{F} is less than about 500 W. For example, the BP_{E} is between about 10 kW and about 25 kW in various embodiments and between about 15 kW and 18 kW in some embodiments. In contrast, BP_{F} is between about 100 W and about 1 kW in some embodiments, and is about 200 W in one embodiment.

The bias power supply 49 may also be an RF power supply and may be configured to provide RF power in the low frequency (LF) to medium frequency (MF) range. In one embodiment, the bias power supply 49 is configured to supply RF bias power at about 400 kHz. For example, during the flash step, the bias power 48 may be provided to the substrate 410 with an RF frequency of 400 kHz and a bias power (SP_{F}) of about 200 W. Other bias power strategies may also be employed, such as square waveforms (which may be referred to as high energy rectangular bias).

The etch precursor gas 441 includes an etchant species that is selective to the target material. For example, in the specific application of a dielectric etch including an oxide, the etchant species may be a fluorocarbon having the chemical formula CₓF_{y}. In various embodiments, the fluorocarbon is a higher molecular weight fluorocarbon having at least two carbon atoms, and (as a result) a higher ratio of carbon to fluorine. For example, the etchant species may be CF₄, C₄F₈, C₅F₈, C₂F₆, C₄F₆, C₅F₆, and others.

The flash precursor gas 442 includes a flash species that functions as an etchant such as an oxygen-based flash species. The flash species targets organic material such as the polymer material. For example, in one embodiment, the flash species is diatomic oxygen (O₂). Other possible flash species include but are not limited to N₂, H₂, SO₂, CO₂, and others.

The flash precursor gas 442 may also include various additional components such as inert species or additives intended to improve desired results. In one embodiment, the flash precursor gas 442 includes carbonyl sulfide (COS). For example, including COS may further reduce bowing leading to other beneficial effects.

Additionally, the flash species (such as oxygen) may react with the polymer material, but does not sputter the polymer material. It may then be beneficial to include inert species (e.g. heavier inert species, but lighter inert species may also be beneficial) in the flash precursor gas 442 to take advantage of improved etching efficiency and bombardment energy afforded by sputtering. In one embodiment, krypton (Kr) may be included in the flash precursor gas 442. In one embodiment, argon (Ar) may be included in the flash precursor gas 442. Some other possible inert materials are helium (He), neon (Ne), and xenon (Xe).

FIG. 5 schematically illustrates two timing diagrams of example methods of etching a target material where the total etch time is the same between the two timing diagrams in accordance with embodiments of the invention. The methods of FIG. 5 may be specific implementations of other methods described herein, such as the method of FIG. 3, for example. Similarly labeled elements may be a previously described.

Referring to FIG. 5, a method 500 is similar to the method 300, but demonstrates varying the number of flashes without varying the total etch time. Source power and bias power may also be varied as in the method 300, but are not shown here for simplicity. Such a scenario may be desirable when the total etch time desired is known or capped and the goal is to optimize other effects with the appropriate number of flashes. As shown, a first configuration 501 repeats a cycle 550 that includes an etch step using etch precursor gas 541 and an etch step duration 551 along with a flash step using a flash precursor gas 542 and a flash step duration 552. The first configuration 501 has five etch steps and four flash steps, as shown.

In the second configuration 502, the number of flash steps is reduced to two resulting in only three etch steps. To keep the total etch time the same, the etch steps are lengthened to an etch step duration 556 resulting in a longer cycle 555. The flash step duration 557 may be the same or different depending on the desired outcome. Here, the flash step duration 557 is the same as the flash step duration 552, which may be desirable when an optimal flash duration is determined and only the number of flashes is being optimized.

Additionally, the duration of both the etch step and the flash step may be dynamically changed in some cases which may be useful when there are effects that change as the etch depth increases or time passes during the etching process.

A related parameter that may have similar effects as the number of flashes is the flash frequency. In particular, as the number of flashes is increased, the frequency of the flashes (equal to 1 over the cycle or period) typically also increases because the total etch time remains mostly the same for a given process. As shown in the first configuration 501 and the second configuration 502, the flash frequency is increased as the number of flashes is increased. In various embodiments, the flash frequency is greater than about one flash step per two minutes. In one some embodiment, the flash frequency is greater than about one flash step per minute.

FIG. 6 schematically illustrates two timing diagrams of example methods of etching a target material where both the total etch time and the total flash time are the same between the two timing diagrams, but the number of flash steps is varied in accordance with embodiments of the invention. The methods of FIG. 6 may be specific implementations of other methods described herein, such as the method of FIG. 3, for example. Similarly labeled elements may be a previously described.

Referring to FIG. 6, a method 600 is similar to the method 500, but demonstrates varying the number of flashes without varying the total etch time or the total flash time. Specifically, a first configuration 601 repeats a cycle 650 that includes an etch step using etch precursor gas 641 and an etch step duration 651 along with a flash step using a flash precursor gas 642 and a flash step duration 652. The first configuration 601 has eight etch steps and seven flash steps, as shown.

In the second configuration 602, the number of flash steps is reduced to two resulting in only three etch steps. To keep the total etch time the same and the total flash time the same, both the etch steps and the flash steps are lengthened to an etch step duration 656 and a flash step duration 657 resulting in a much longer cycle 655. This scenario may be desirable when the total flash time desired is known or capped and the other desired outcomes can be met even with reduced flash frequency.

FIG. 7 illustrates an example method of etching a target substrate in accordance with embodiments of the invention. The method of FIG. 7 may be combined with other methods and performed using the systems and apparatuses as described herein. For example, the method of FIG. 7 may be combined with any of the embodiments of FIGS. 1-6. Although shown in a logical order, the arrangement and numbering of the steps of FIG. 7 are not intended to be limited. The method steps of FIG. 7 may be performed in any suitable order or concurrently with one another as may be apparent to a person of skill in the art.

Referring to FIG. 7, step 701 of a method 700 of etching a target substrate is to performing an etch step for a first duration to etch a target material exposed in openings of a patterned mask material by generating plasma from an etch precursor gas comprising an etchant species. A flash step is performed for a second duration in step 702 after the first duration to remove polymer material accumulated at the openings during the etch step by generating plasma from a flash precursor gas comprising a flash species different from the etchant species. The flash precursor gas includes oxygen and no fluorocarbons. The method 700 is then cyclically performed by repeating step 701 and step 702 as indicated by step 703.

FIG. 8 illustrates another method of etching a target substrate in accordance with embodiments of the invention. The method of FIG. 8 may be combined with other methods and performed using the systems and apparatuses as described herein. For example, the method of FIG. 8 may be combined with any of the embodiments of FIGS. 1-7. Although shown in a logical order, the arrangement and numbering of the steps of FIG. 8 are not intended to be limited. The method steps of FIG. 8 may be performed in any suitable order or concurrently with one another as may be apparent to a person of skill in the art.

Referring to FIG. 8, step 801 of a method 800 of etching a target substrate is to perform an etch step for a first duration by generating plasma from an etch precursor gas comprising an etchant species to etch a dielectric exposed in openings of a patterned hard mask material of a substrate. The dielectric includes an oxide and the etchant species has greater reactivity toward the oxide than toward the hard mask material. A flash step is performed for a second duration in step 802 after the first duration to remove polymer material accumulated at the openings during the etch step by generating plasma from a flash precursor gas comprising a flash species and providing bias power at the substrate. The flash species has greater reactivity toward the polymer material than toward the oxide. The method 800 is then cyclically performed by repeating step 801 and step 802 as indicated by step 803.

FIG. 9 qualitatively illustrates example dimples exhibiting greater defects contrasted with example dimples exhibiting lesser defects in accordance with embodiments of the invention. For example, FIG. 9 may be used as a specific qualitative example for visualizing the possible advantages regarding defects transferred to an underlying layer afforded by the invention.

Referring to FIG. 9, a qualitative illustration 900 of two underlying layers is provided with one underlying layer 901 showing dimples 97 with greater defects and another underlying layer 902 showing dimples 98 with lesser defects. Although the goal is to transfer a highly regular (e.g. circular) dimple into an underlying layer, this ideal result may not be attainable in practice. Therefore, the example dimples are provided to demonstrate the differences between greater defects, such as high degrees of distortion and CER in the dimples 97, and lesser defects, such as the quasi-circular shapes with smooth edges in the dimples 98.

It should be noted that these dimples 98 are much closer than the dimples 97 to the ideal perfectly circular dimple 28 shown as transferred into the underlying layer 18 when no secondary facet 23 is present in FIG. 1. The dimples 98 are much more smooth (e.g. lower CER), much more uniform (e.g. lower distortion), and much larger (e.g. greater B/T ratio resulting in larger dimple sizes that more accurately reflect the desired pattern.

Example embodiments of the invention are summarized here. Other embodiments can also be understood from the entirety of the specification as well as the claims filed herein.

Example 1. A method of etching a target material using plasma, the method including cyclically performing the following steps: performing an etch step for a first duration to etch a target material exposed in openings of a patterned mask material by generating plasma from an etch precursor gas including an etchant species; and performing a flash step for a second duration after the first duration to remove polymer material accumulated at the openings during the etch step by generating plasma from a flash precursor gas including a flash species different from the etchant species, the flash precursor gas including oxygen and no fluorocarbons.

Example 2. The method of example 1, where the flash precursor gas includes diatomic oxygen (O₂).

Example 3. The method of example 2, where the flash precursor gas further includes carbonyl sulfide (COS).

Example 4. The method of one of examples 1 to 3, where the flash precursor gas further includes an inert gas.

Example 5. The method of example 4, where the inert gas is krypton (Kr).

Example 6. The method of one or examples 1 to 5, where the etchant species includes a fluorocarbon.

Example 7. The method of one of examples 1 to 6, where the fluorocarbon is a higher molecular weight fluorocarbon having at least two carbon atoms.

Example 8. A method of etching a dielectric using plasma, the method including cyclically performing the following steps: performing an etch step for a first duration to etch a dielectric exposed in openings of a patterned hard mask material of a substrate by generating plasma from an etch precursor gas comprising an etchant species, the dielectric including an oxide and the etchant species having greater reactivity toward the oxide than toward the hard mask material; and performing a flash step for a second duration after the first duration to remove polymer material accumulated at the openings during the etch step by generating plasma from a flash precursor gas including a flash species and providing bias power at the substrate, the flash species having greater reactivity toward the polymer material than toward the oxide.

Example 9. The method of example 8, where the bias power is radio frequency power in the low frequency (LF) range.

Example 10. The method of one of examples 8 and 9, where the etch step further includes providing bias power at the substrate at a first bias power level, and where the flash step includes providing the bias power at the substrate at a second bias power level that is less than the first bias power level.

Example 11. The method of example 10, where the first bias power level during the etch step is greater than about 2 kW, and where the second bias power level during the flash step is less than about 500 W.

Example 12. The method of one of examples 8 to 11, where the etch step includes generating plasma from the etch precursor gas by coupling source power to the etch precursor gas at a first source power level, and where the flash step includes generating plasma from the flash precursor gas by coupling source power to the flash precursor gas at a second source power level that is less than the first source power level.

Example 13. The method of one of examples 8 to 12, where the dielectric further includes a nitride.

Example 14. The method of one of examples 8 to 13, where the patterned hard mask material is an amorphous carbon layer (ACL).

Example 15. The method of one of examples 8 to 14, where the second duration is less than about 20 s.

Example 16. The method of one of examples 8 to 15, where the flash step is performed at a flash frequency greater than about one flash step per minute.

Example 17. A plasma etching system including: a plasma chamber; a substrate holder disposed in the plasma chamber and configured to support a substrate; and a controller operationally coupled to the chamber and configured to cyclically perform an etch step for a first duration to etch a target material exposed in openings of a patterned mask material of the substrate by generating plasma from an etch precursor gas including an etchant species, and a flash step for a second duration after the first duration to remove polymer material accumulated at the openings during the etch step by generating plasma from a flash precursor gas including a flash species different from the etchant species, the flash precursor gas including oxygen and no fluorocarbons.

Example 18. The plasma etching system of example 17, where the controller is further configured to cyclically perform the etch step and the flash step without evacuating the plasma chamber between steps.

Example 19. The plasma etching system of one of examples 17 and 18, where the controller is further configured to provide radio frequency (RF) bias power in the low frequency (LF) range at the substrate during the flash step.

Example 20. The plasma etching system of example 19, where the controller is further configured to provide the bias power at the substrate during the etch step at a bias power level between about 10 kW and about 25 kW, provide the bias power at the substrate during the flash step at a bias power level between about 100 W and about 1 kW, couple source power to the etch precursor gas during the etch step at a source power level between about 3 kW and about 8 kW, couple the source power to the flash precursor gas during the flash step at a source power level between about 500 W and about 2 kW. While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of etching a target material using plasma, the method comprising cyclically performing the following steps:
performing an etch step for a first duration to etch a target material exposed in openings of a patterned mask material by generating plasma from an etch precursor gas comprising an etchant species; and
performing a flash step for a second duration after the first duration to remove polymer material accumulated at the openings during the etch step by generating plasma from a flash precursor gas comprising a flash species different from the etchant species, the flash precursor gas comprising oxygen and no fluorocarbons.

2. The method of claim 1, wherein the flash precursor gas comprises diatomic oxygen (O₂).

3. The method of claim 2, wherein the flash precursor gas further comprises carbonyl sulfide (COS).

4. The method of claim 1, wherein the flash precursor gas further comprises an inert gas.

5. The method of claim 4, wherein the inert gas is krypton (Kr).

6. The method of claim 1, wherein the etchant species comprises a fluorocarbon.

7. The method of claim 1, wherein the fluorocarbon is a higher molecular weight fluorocarbon having at least two carbon atoms.

8. A method of etching a dielectric using plasma, the method comprising cyclically performing the following steps:
performing an etch step for a first duration to etch a dielectric exposed in openings of a patterned hard mask material of a substrate by generating plasma from an etch precursor gas comprising an etchant species, the dielectric comprising an oxide and the etchant species having greater reactivity toward the oxide than toward the hard mask material; and
performing a flash step for a second duration after the first duration to remove polymer material accumulated at the openings during the etch step by generating plasma from a flash precursor gas comprising a flash species and providing bias power at the substrate, the flash species having greater reactivity toward the polymer material than toward the oxide.

9. The method of claim 8, wherein the bias power is radio frequency power in the low frequency (LF) range.

10. The method of claim 8, wherein the etch step further comprises providing bias power at the substrate at a first bias power level, and wherein the flash step comprises providing the bias power at the substrate at a second bias power level that is less than the first bias power level.

11. The method of claim 10, wherein the first bias power level during the etch step is greater than about 2 kW, and wherein the second bias power level during the flash step is less than about 500 W.

12. The method of claim 8, wherein the etch step comprises generating plasma from the etch precursor gas by coupling source power to the etch precursor gas at a first source power level, and wherein the flash step comprises generating plasma from the flash precursor gas by coupling source power to the flash precursor gas at a second source power level that is less than the first source power level.

13. The method of claim 8, wherein the dielectric further comprises a nitride.

14. The method of claim 8, wherein the patterned hard mask material is an amorphous carbon layer (ACL).

15. The method of claim 8, wherein the second duration is less than about 20 s.

16. The method of claim 8, wherein the flash step is performed at a flash frequency greater than about one flash step per minute.

17. A plasma etching system comprising:
a plasma chamber;
a substrate holder disposed in the plasma chamber and configured to support a substrate; and
a controller operationally coupled to the chamber and configured to cyclically perform
an etch step for a first duration to etch a target material exposed in openings of a patterned mask material of the substrate by generating plasma from an etch precursor gas comprising an etchant species, and
a flash step for a second duration after the first duration to remove polymer material accumulated at the openings during the etch step by generating plasma from a flash precursor gas comprising a flash species different from the etchant species, the flash precursor gas comprising oxygen and no fluorocarbons.

18. The plasma etching system of claim 17, wherein the controller is further configured to cyclically perform the etch step and the flash step without evacuating the plasma chamber between steps.

19. The plasma etching system of claim 17, wherein the controller is further configured to provide radio frequency (RF) bias power in the low frequency (LF) range at the substrate during the flash step.

20. The plasma etching system of claim 19, wherein the controller is further configured to
provide the bias power at the substrate during the etch step at a bias power level between about 10 kW and about 25 kW,
provide the bias power at the substrate during the flash step at a bias power level between about 100 W and about 1 kW,
couple source power to the etch precursor gas during the etch step at a source power level between about 3 kW and about 8 kW,
couple the source power to the flash precursor gas during the flash step at a source power level between about 500 W and about 2 kW.
